(19) United States
(12) Patent Application Publication
(10) Pub. No.: US 2011/0305922 A1
(43) Pub. Date: Dec. 15, 2011

(54) METHOD FOR APPLYING A COATING TO WORKPIECES AND/OR MATERIALS COMPRISING AT LEAST ONE READILY OXIDIZABLE NONFERROUS METAL

(75) Inventor: Oliver Nöll, Schwalmtal (DE)

(73) Assignee: Surcoatec GmbH, Dortmund (DE)

(21) Appl. No.: 13/201,378

(22) PCT Filed: Feb. 12, 2010
(86) PCT No.: PCT/EP2010/000889

§ 371 Date: Aug. 29, 2011

(30) Foreign Application Priority Data
Feb. 12, 2009 (DE) 10 2009 000 821.7

(51) Int. Cl. B32B 15/00; B05D 3/12; B32B 15/20; C23C 14/34; B32B 15/01; B32B 15/04; B05D 3/10; B05D 7/14

(52) U.S. Cl. 428/668; 427/535; 204/192.1; 428/457; 428/450

(57) ABSTRACT

The present invention relates to a method for applying a coating to workpieces and/or materials containing at least one readily oxidizable nonferrous metal or an alloy containing at least one readily oxidizable nonferrous metal. The method comprises the following steps:
b) Pretreating the workpiece and/or material by plasma reduction
c) Applying a cover layer by plasma coating in a plasma coating chamber (FIG. 4a).

### TECHNICAL FIELD

Workpieces and/or materials containing oxidizable nonferrous metals are finding increasing use in recent times. These include in particular light metals, which combine high mechanical strength with low specific gravity. These types of metals are therefore in great demand, in particular for weight-critical applications such as in the automotive and aerospace sectors.

Thus, for comparable strength, magnesium, for example, has a specific density of 1.74 g/cm³, while aluminum has a density of 2.7 g/m³.

Although many readily oxidizable nonferrous metals are some of the most abundant elements in the geosphere (magnesium, for example, with a percentage of 1.94%, is the eighth most abundant element), under atmospheric conditions—i.e., in the overall geosphere in particular—they essentially do not occur in elemental form due to their extremely rapid reaction with atmospheric oxygen.

This is due to the fact that, compared to iron or hydrogen, these metals have a negative standard electrochemical potential.

The term “readily oxidizable nonferrous metal” as used herein thus refers to technical metals and metal alloys which have a negative standard potential compared to iron. Many of these nonferrous metals are light metals. “Light metal” refers to any metal having a specific density of less than 6 g/cm³. The following table lists readily oxidizable nonferrous metals which are important within the meaning of the present definition; iron and hydrogen (shown in italic) are used as comparative materials.

TABLE 1

| | Oxidized | Standard | Specific |
|---|---|---|---|
| | form | potential E₀ (V) | density (g/cm³) |
| Hydrogen | H⁺ | 0 | n/a |
| Iron | Fe²⁺ | −0.04 | 7.87 |
| Tin | Sn²⁺ | −0.14 | 7.3 |
| Zinc | Zn²⁺ | −0.76 | 7.1 |
| Titanium | Ti³⁺ | −1.21 | 4.51 |
| Aluminum | Al³⁺ | −1.66 | 2.7 |
| Beryllium | Be²⁺ | −1.85 | 1.85 |
| Magnesium | Mg²⁺ | −2.38 | 1.74 |

Readily oxidizable nonferrous metals always occur in the geosphere in the form of oxides or other salts, for example in the form of magnesium oxide (MgO), magnesium chloride (MgCl₂), or magnesium sulfate (MgSO₄).

Magnesium, for example, has relatively low melting and boiling points. When heated, it burns above 500° C. with a brilliant white flame to form magnesium oxide and magnesium nitride:

2Mg+O₂→2MgO

3Mg+N₂→Mg₃N₂

Magnesium also burns in other gases in which oxygen is chemically bound, for example carbon dioxide or sulfur dioxide.

Magnesium powder dissolves in boiling water to form magnesium hydroxide and hydrogen:

Mg+2H₂O→Mg(OH)₂+H₂

With acids, the corresponding salts are formed with evolution of hydrogen, for example in reaction with hydrochloric acid:

Mg+2HCl→MgCl₂+H₂

In order to provide magnesium in elemental form for industrial use, anhydrous magnesium chloride recovered from sea water is subjected to the fused salt electrolysis process. Alternatively, magnesium is obtained by thermal reduction of magnesium oxide. Both processes are very energy-intensive.

Pure magnesium is rarely used in industrial applications due to the low degree of hardness and high susceptibility to corrosion. Therefore, magnesium in particular is frequently used in the form of alloys with other metals, in particular aluminum and zinc (see Table 3). These alloys are characterized by their low density, high strength, and corrosion resistance.

Beryllium generally occurs in the geosphere as bertrandite (4BeO.2SiO₂.H₂O), beryl (Be₃Al₂(SiO₃)₆), beryllium fluoride, or beryllium chloride. Elemental beryllium may be obtained by reduction of beryllium fluoride with magnesium at 900° C., or by fused salt electrolysis of beryllium chloride or beryllium fluoride.

Aluminum generally occurs in the geosphere chemically bound in aluminosilicates, aluminum oxide (corundum), or aluminum hydroxide (Al(OH)₃ and AlO(OH)). For recovery, the aluminum oxide/hydroxide mixture contained in bauxite is dissolved with sodium hydroxide solution and then combusted in a rotary tubular kiln to form aluminum oxide (Al₂O₃), followed by fused salt electrolysis. The aluminum oxide is dissolved in a cryolite melt to lower the melting point. During the electrolysis, elemental aluminum is obtained at the cathode which forms the base of the vessel.

Titanium generally occurs in the geosphere as ilmenite (FeTiO₃), perovskite (CaTiO₃), rutile (TiO₂), titanite (CaTi[SiO]O), or barium titanate (BaTiO₃). For recovery, enriched titanium dioxide is reacted with chlorine, with heating, to form titanium tetrachloride. This is followed by reduction to titanium, using liquid magnesium. To produce processible alloys, the obtained titanium sponge must be remelted in a vacuum arc furnace.

Zinc generally occurs in the geosphere in the form of zinc sulfide ores, smithsonite (ZnCO₃), or, less commonly, as hemimorphite (Zn₄(OH)₂[Si₂O₇]) or franklinite ((Zn,Fe,Mn)(Fe₂Mn₂)O₄). Recovery is carried out by roasting zinc sulfide ores in air. This results in zinc oxide, which is combined with finely ground coal and heated in a blast furnace at 1100-1300° C. Carbon monoxide is initially formed, which reduces the zinc oxide to metallic zinc.

Tin generally occurs in the geosphere as tin oxide (SnO₂, also referred to as tinstone or cassiterite). For recovery, tinstone is pulverized and then enriched using various processes (slurrying, electrical/magnetic separation). After reduction with carbon, the tin is heated to just above its melting temperature, allowing it to flow off without higher-melting impurities.

For the reasons stated above, workpieces made of readily oxidizable nonferrous metals, as well as workpieces made of the alloys thereof (if untreated), always have an oxidized surface layer composed of magnesium oxide, for example, which results from spontaneous oxidation with atmospheric oxygen.

If workpieces made of readily oxidizable nonferrous metals are not protected from atmospheric oxygen, they sometimes oxidize with deep penetration within a short period of time, with consequences similar to the corrosion of steel, except that this process occurs much more quickly, and is further assisted by moisture in particular. The latter applies in particular to workpieces made of magnesium or magnesium alloys, for example.

For this reason, workpieces made of readily oxidizable nonferrous metals must be surface-treated in such a way that they are protected from the effect of atmospheric oxygen. Various methods in industrial technology are known for this purpose.

In particular for automotive manufacturing, in which light metals are in great demand due to their favorable strength-to-specific density ratio, light metals are lacquered in a known manner, for example by dip coating, spray painting, or powder coating. However, this well-established process has the disadvantage that lacquers have low resistance to hard impacts and tend to chip. However, if the lacquer layer is disrupted at a location and the workpiece or material comes into contact with atmospheric oxygen, the latter immediately causes oxidation at this location, possibly resulting in the development of an oxidation nucleus which is not controllable, even by subsequent recoating. As a result, the workpiece may have to be replaced, if this is possible at all.

Electroplating of workpieces made of readily oxidizable nonferrous metals is also known. Although such plating improves the corrosion properties, it frequently does not have sufficient adherence to the workpieces, and in addition has low mechanical resistance.

In addition, workpieces made of readily oxidizable nonferrous metals may be provided with an oxide ceramic layer, using electrolytic coating processes. An external power source is used, and the workpiece to be coated is connected as the anode. A salt solution is used as electrolyte.

So-called anodization is carried out via plasma discharges in the electrolyte at the surface of the workpiece to be coated. The layer is composed of a crystalline oxide ceramic, half of which grows into the magnesium material, and which contains a high percentage of very resistant compounds such as spinels, for example MgAl₂O₄. Edges, cavities, and reliefs are uniformly coated; i.e., edge buildup does not occur as in electroplating processes.

Thermal coating processes for workpieces made of readily oxidizable nonferrous metals include high-speed flame spraying, atmospheric plasma spraying, and electric arc spraying. Well-adhering wear protection layers may generally be obtained using these processes.

However, all of the referenced processes have the common feature that, although the obtained coatings prevent corrosion or oxidation of the workpiece within certain limits, they do not meet extremely stringent requirements for adhesion and/or mechanical resistance; i.e., under certain conditions they may delaminate, chip, or become damaged, thus exposing the coated workpiece to oxidation or corrosion.

For this reason, the referenced processes are not suitable for various demanding fields of application, for example automotive, aircraft construction, hydraulic engineering, surgery, tool manufacturing, or aerospace engineering.

For example, it has been reported that painted magnesium workpieces, as currently used in automotive manufacturing, may have to be completely replaced after paint chipping, which may easily occur during parking maneuvers, for example, since, even if the paint is immediately repaired, the brief period of time during which the magnesium workpiece has been exposed to atmospheric oxygen at that location without protection initiates a corrosion process which ultimately uncontrollably destroys the entire workpiece.

### Object of the Present Invention

The object of the present invention, therefore, is to provide a method for coating workpieces and/or materials containing at least one readily oxidizable nonferrous metal or an alloy containing readily oxidizable nonferrous metals, wherein the coating has better adhesion properties than [in] the processes known from the prior art.

A further object is to provide a method for coating workpieces and/or materials containing at least one readily oxidizable nonferrous metal or an alloy containing readily oxidizable nonferrous metals, wherein the coating has better mechanical resistance than [in] the processes known from the prior art.

A further object is to provide a method for coating workpieces and/or materials containing at least one alkaline earth metal, a readily oxidizable nonferrous metal, or an alloy containing readily oxidizable nonferrous metals, which is suitable for coating workpieces subjected to high load.

These objects are achieved by the features of the main claim.

### DESCRIPTION OF THE PREFERRED EMBODIMENTS

Accordingly, a method [is provided] for applying a coating to workpieces and/or materials containing at least one readily oxidizable nonferrous metal or an alloy containing at least one readily oxidizable nonferrous metal, the method comprising the following steps:
b) Pretreating the workpiece and/or material by plasma reduction
c) Applying a cover layer by plasma coating in a plasma coating chamber.

The term “plasma coating” (plasma enhanced chemical vapor deposition (PECVD)) refers to a method for applying coatings to workpieces and/or materials.

The term “plasma reduction” as used herein refers to a process carried out in a plasma coating chamber, in which oxygen is removed from the oxides (generally metal oxides) present at the surface of the workpiece and/or material. The metal oxides are thus reduced to their elemental metal form. Such a step is therefore also referred to as “metallization.”

It is preferably provided that the readily oxidizable nonferrous metal or alloy thereof is magnesium or a magnesium alloy.

It is also preferably provided that the reaction gas in step b) contains at least hydrogen, which may be used in a mixture with argon.

In the case that the readily oxidizable nonferrous metal is magnesium, the process is subject to the following scheme:

MgO+2[H]→Mg+H₂O (optionally in the presence of argon)

Argon, as an optional component, does not take part in the reaction.

The following schemes, for example, apply for other readily oxidizable nonferrous metals:

Al₂O₃+6[H]→2Al+3H₂O (optionally in the presence of argon)

ZnO+2[H]→Zn+H₂O (optionally in the presence of argon)

BeO+2[H]→Be+H₂O (optionally in the presence of argon)

TiOx+X[H]→Ti+XH₂O (optionally in the presence of argon)

Compared to other surface reduction methods, the plasma reduction process has the following advantages:
a) The method may be carried out in the same apparatus as for the subsequent plasma coating, and
b) The method may be carried out at low temperatures.

Thus, for example, methods for surface reduction/metallization of ferrites are known in which the workpiece and/or material is heat-treated and brought into contact with a gaseous reducing agent such as hydrogen or ammonia (or mixtures thereof with nitrogen or inert gases). In the subsequent heat treatment in a heating chamber, temperatures between 600° C. and 800° C. are employed to completely reduce the surface oxides to their metal form. However, this method is not suited for treating alkaline earth metals, since magnesium, for example, has a melting temperature of 650° C. at standard pressure, and under vacuum, even as low as 180° C., depending on the alloy.

It is also preferably provided that the feed of the reaction gas is periodically modulated in step b).

As previously mentioned, hydrogen is preferably used as the reaction gas. As the result of periodic modulation, it may be achieved that a large quantity of reaction gas flows into the chamber for certain phases, while for other phases only a small quantity of reaction gas flows into the chamber.

The reaction gas may be modulated, for example, using a processor-controlled mass flow controller (MFC) or a processor-controlled servo-assisted valve. The modulation may be carried out, for example, in a sinusoidal manner, or also in a square or triangular manner.

The feed, which is measured in units of standard cubic centimeters min⁻¹ (sccm), may preferably be modulated in a range between ≧10 and ≦1000 sccm, particularly preferably between ≧50 and ≦300 sccm (also see FIG. 1).

As a result of the periodic modulation of the reaction gas feed, the fissured surface of the workpiece and/or material is taken into account, since basically this is the only way to adequately reduce metal oxide residues present in deep channels and microcavities in the surface of the workpiece and/or material, as well as metal oxide residues adhering to flat passages on the surface.

For the metal oxide residues adhering to flat passages on the surface, high feed rates are ideal, since rapid metallization of these easily accessible passages is thus made possible.

On the other hand, it is important that in particular the metal oxide residues present in deep channels in the surface of the workpiece and/or material come into contact with the ionized reaction gas only when the reaction gas is flowing into the chamber at low feed rates, whereas the metal oxide residues adhering to the flat passages on the surface require higher feed rates in order to be reduced quickly enough.

The reason is that at low gas concentrations (i.e., low feed rates), the gas ions in the plasma may be accelerated much more intensely than at higher gas concentrations (i.e., high feed rates). This is due to the fact that at low gas concentrations, the gas ions collide with one another much less frequently, and thus undergo less deceleration than at higher gas concentrations.

For this reason, the ion vibration generated by the alternating field also has a much greater amplitude at low gas concentrations than at higher gas concentrations.

As a result of the higher velocity of the gas ions, combined with a greater oscillation amplitude, even metal oxide residues present in deep channels and microcavities in the surface of the workpiece and/or material may be adequately reduced.

Thus, at a constant excitation frequency the periodic modulation of the reaction gas feed results in a periodically changing velocity and oscillation amplitude of the gas ions.

The metal oxide layer present on the surface may be so thick that it cannot undergo complete metallization via plasma reduction. Therefore, in one preferred embodiment of the method according to the invention, prior to step b) the method has at least one step

a.2) Activating the Workpiece and/or the Material by Sputtering.

The term “activation” as used herein refers to the active removal or ablation of an impurity, in particular a metal oxide layer, that is present on the surface of the workpiece and/or the material.

The term “sputtering” or “sputter etching” as used herein refers to a physical process in which the atoms are removed from a solid by bombardment with high-energy ions and pass into the gaseous phase. These ions, similarly as for PECVD, are produced by generating a plasma using a high-frequency alternating electromagnetic field in a vacuum chamber. Inert gases are generally suitable as reaction gas, for example argon (Ar₂), which, with the exception of helium and neon, have a high kinetic energy due to their high molecular weight, and are therefore particularly well suited for efficient surface removal.

In principle, O₂ represents an attractive reaction gas for the sputtering, since the ionized oxygen atoms likewise have a high molecular weight. In addition, oxygen is very inexpensive. However, O₂ cannot be used for sputtering of a material or workpiece containing alkaline earth metal as pretreatment or activation for subsequent treatment, since this has an oxidizing effect on the metallic surface, upon which a fairly thick metal oxide layer forms and thus passivates the surface—i.e., the opposite effect that is desired for the method according to the invention.

In fact, in the present case a gas having a reducing effect, such as H₂, would be ideal, since this gas would be able to likewise prevent or even eliminate passivation of the metal surface. However, H₂ is not suitable for the sputtering on account of its low molecular weight and, therefore, low kinetic energy.

For this reason, according to the invention a nonreactive inert gas from main group VIII of the periodic table is preferably used, preferably argon. However, hydrogen, which has been mentioned as a gas having a reducing effect, is not used according to the invention until step b), i.e., for the plasma reduction. The steps of activation (i.e., the removal of surface impurities, in particular metal oxides) and metallization (i.e., the reduction of remaining metal oxide residues) thus take place in a division of labor, the first step being carried out using argon, and the second step being carried out using hydrogen.

As indicated above, it must be assumed that the method step of activation is not so thorough that it always completely removes all metal oxide at the surface. Thus, metal oxide residues often remain which likewise must be removed in order to prevent subsequent reoxidation of the workpiece and/or material. Therefore, according to the main claim of the present invention, step b) (plasma reduction) is still necessary even when a sputtering step has been carried out beforehand. It is noted that sputtering is an ablative method (i.e., metal oxides are removed), while plasma reduction is a converting method (i.e., metal oxides are reduced to their elemental form).

It is particularly advantageous that the sputtering step and the plasma reduction step may be carried out in the same apparatus, namely, a plasma coating chamber. Thus, a continuous vacuum may be ensured during and between the two steps, which prevents spontaneous re-formation of metal oxides at the surface of the workpiece and/or material between the two method steps. In addition, the complexity of the method is significantly reduced, and the method is economically competitive.

Since argon is preferably used for the sputtering, and H₂ in addition to argon may be used for the plasma reduction, steps a.2) and b) may also seamlessly merge together. After the sputtering step using the “ramps” described below, the H₂ gas feed is gradually ramped up, while the argon gas feed, if applicable, is ramped down. At the same time, the process parameters, in particular the bias voltage, are correspondingly adjusted as necessary in a continuous or abrupt manner.

On this basis, a preferred embodiment of the method according to the invention in which the step
a.2) Activating the workpiece and/or the material by sputtering
   is carried out concurrently with step b) appears to be particularly logical. This is particularly meaningful due to the fact that (i) during sputtering using argon, any hydrogen which may be present does not have an interfering effect, and (ii) argon may be used anyway for the plasma reduction with hydrogen.

The sputtering preferably takes place using the following process parameter ranges:

TABLE 2

| | | | Particularly |
|---|---|---|---|
| Parameter | In general | Preferred | preferred |
| Reaction gas | Inert gas from | Ar₂ | Ar₂ |
| | main group VIII | | |
| Bias voltage (V) | ≧100 and ≦500 | ≧200 and ≦400 | ≧300 and ≦350 |
| Chamber pressure (P) | ≧0.001 and ≦4 | ≧0.001 and ≦1 | ≧0.001 and ≦0.5 |
| Temperature in | ≧30 and ≦200 | ≧30 and ≦100 | ≧30 and ≦50 |
| the chamber (° C.) | | | |
| Gas flow (sccm) | ≧20 and ≦500 | ≧20 and ≦300 | ≧20 and ≦100 |

In addition, it is preferably provided that prior to step b) the method according to the invention has at least one step

a.1) Treating the Surface of the Workpiece and/or Material Using at Least One Abrasive Process.

Elemental alkaline earth metals, in particular magnesium, are extremely reactive even when present in alloys. Workpieces or materials which are exposed to atmospheric oxygen therefore form a very thick oxide layer very quickly. For this reason, in some cases it is recommended that this oxide layer first be removed by mechanical abrasion before the workpieces or materials undergo the above-described sputtering step.

The abrasive process is preferably at least one process selected from the group containing
grinding
sandblasting
shot peening
brushing and/or
polishing.

Each of these processes is preferably carried out in the dry state, since there is a risk of promoting oxidation of the material surface when the process is carried out in the presence of water.

This step is particularly meaningful since the removal rate for abrasive processes may be much higher than for sputtering (<2 μm h⁻¹ for sputtering versus >1 mm h⁻¹, for example, for sandblasting).

However, this step is an optional step which on the one hand is not absolutely necessary for workpieces that are not highly oxidized, and which on the other hand is not able to replace the sputtering step.

The latter is the case in particular due to the fact that new metal oxide spontaneously forms on the surface of the workpieces or materials immediately after the abrasive treatment, which generally takes place under atmospheric conditions. However, combining an abrasive method step with the plasma reduction step in the same apparatus is not meaningful for technical reasons.

It is particularly preferably provided that the readily oxidizable nonferrous metal is at least one metal selected from the group containing tin, zinc, titanium, aluminum, beryllium, and/or magnesium or a magnesium alloy. The at least one nonferrous metal may also be present in an alloy. The following table shows a non-limiting example of a selection of preferred magnesium alloys and the ASTM codes for the alloy elements of magnesium.

TABLE 3

| Alloy | Composition | Letter code | Alloy element |
|---|---|---|---|
| AZ91 | (Aluminum/zinc 9%:1%) | A | Aluminum |
| AZ91D | | B | Bismuth |
| AZ91Ca | | C | Copper |
| AZ81 | | D | Cadmium |
| AZ80 | | E | Rare earths |
| AM60 | (Aluminum/ | F | Iron |
| | manganese 6%:<1%) | | |
| AM50 | | H | Thorium |
| AM30 | | K | Zirconium |
| AZ63 | | L | Lithium |
| AZ61A | | M | Manganese |
| AJ62A | | N | Nickel |
| AE44 | | P | Lead |
| AE42 | | Q | Silver |
| AZ31B | | R | Chromium |
| AS41 | | S | Silicon |
| AS21 | | T | Tin |
| WE43 | | W | Yttrium |
| ZE41 | | Y | Antimony |
| A6 | | Z | Zinc |
| ZK60A | | | |

Further preferred alloys that are used are listed in the following table:

TABLE 4

| Alloy | Composition |
|---|---|
| AlBeMet | 62% Be, 38% Al |
| Beryllium copper | 0.4 to 2% Be, 0 to 2.7% Co, remainder Cu |
| Brass | Zn/Cu, Cu content always ≧50% by weight |
| Bronze | Sn/Cu, Sn content always ≦40% by weight |

The plasma reduction preferably takes place using the following process parameter ranges:

TABLE 5

| | | | Particularly |
|---|---|---|---|
| Parameter | In general | Preferred | preferred |
| Reaction gas | H₂, optionally acted on by Ar₂ | | |
| Bias voltage (V) | ≧100 and ≦500 | ≧200 and ≦400 | ≧300 and ≦350 |
| Chamber pressure (P) | ≧0.001 and ≦4 | ≧0.001 and ≦1 | ≧0.001 and ≦0.5 |
| Temperature in the | ≧30 and ≦200 | ≧30 and ≦100 | ≧30 and ≦50 |
| chamber (° C.) | | | |
| Gas flow (sccm) | ≧20 and ≦500 | ≧20 and ≦300 | ≧20 and ≦100 |
| Frequency of the | 13.37 MHz | 13.37 MHz | 13.37 MHz |
| alternating | | | |
| electromagnetic field | | | |
| Number of cycles of | >10 | >40 | >60 |
| periodic modulation | | | |
| Duration of one | >100 | >200 | >500 |
| cycle of periodic | | | |
| modulation (s) | | | |

It is also preferably provided that the cover layer is a layer selected from the group containing
carbon-containing layers
silicon-containing layers
titanium-containing layers
tungsten-containing layers
tungsten carbide-containing layers
vanadium-containing layers and/or
copper-containing layers.

As previously mentioned, according to the present invention the high-strength cover layer is applied by plasma coating. A reaction gas is used in addition to an inert protective gas.

Methane (CH₄), ethene (C₂H₄), or acetylene (C₂H₂) in particular is used as reaction gas for producing a carbon-containing coating, for example diamond-like carbon (DLC), which often has diamond-like properties and structures since the carbon atoms are predominantly present as sp3 hybrids.

Methyltrichlorosilane (CH₃SiCl₃), tetramethylsilane (TMS), or tetramethyldisiloxane (C₄H₁₄OSi₂), for example, is used as reaction gas for depositing a silicon-containing layer.

In contrast, when the reaction gases ammonia and dichlorosilane are used, a silicon nitride layer is produced as cover layer. The reaction gases silane and oxygen are used for silicon dioxide layers. Such layers are likewise particularly preferred embodiments of the invention.

For production of metal/silicon hybrids (silicides) as a cover layer or tungsten-containing cover layers, tungsten hexafluoride (WF₆) or tungsten(IV) chloride (WCl₄), for example, is used as reaction gas.

Titanium nitride layers as a cover layer for hardening tools are produced from tetrakis(dimethylamido)titanium (TDMAT) and nitrogen. Silicon carbide layers are deposited from a mixture of hydrogen and methyltrichlorosilane (CH₃SiCl₃).

Copper(II) hexafluoroacetylacetonate hydrate, copper(II) 2-ethyl hexanoate, and copper(II) fluoride (anhydrous) in particular are used for depositing a cover layer containing copper.

Vanadium(V) triisopropoxy oxide (C₉H₂₁O₄V) in particular is used for depositing a cover layer containing vanadium.

Basically, for deposition from the gaseous phase it must be possible for the material to be deposited to be made available for the method in gaseous form (“reaction gas”).

As previously described, in the above cases separation media are present in a gaseous physical state; these separation media may therefore be used as reaction gases without further modifications.

However, there is a great need for coatings which are not based, or not based exclusively, on carbon and/or silicates. One example is semiconductor metals, which demonstrate special properties when applied in thin layers on a substrate material. For these materials there are generally no precursors available that are gaseous at room temperature, i.e., which contain the material in question and/or which provide the reaction gases.

Also mentioned are metals such as titanium which, similarly to DLC, have particularly high strength.

Materials which exist in gaseous form at room temperature or liquid, highly volatile materials are suitable for this purpose. A device is known for the first time from DE 10 2007 020 852 by the present applicant, by means of which materials which exist in solid or liquid form at room temperature (C₁₂H₂₈O₄Ti, for example) may be provided for deposition from the gaseous phase in order to functionally dope carbon oxides or silicon oxides, or to produce pure coatings based on said solids.

This is achieved using a gas feed system for a phase deposition reaction chamber having a gas feed device which has at least one heating element for heating a separation medium which is solid or liquid at room temperature, and for converting the separation medium to the gaseous phase. The system also has a gas feed device for transporting the separation medium, converted to the gaseous phase, from the gas feed device into the gaseous phase deposition reaction chamber. Reference is made herein to the content of said patent application in its entirety.

The disclosure content of DE 10 2007 020 852 is hereby incorporated in its entirety into the present patent application.

Accordingly, in one preferred embodiment of the method according to the invention it is provided that a solid or liquid precursor for a reaction gas in a gas feed system provided upstream from the plasma coating chamber is heated, brought into the vapor phase under vacuum, and subsequently fed into the plasma coating chamber via a gas feed device.

The system is thermally set up in such a way that, as the result of continuous thermal insulation and constant thermal equilibration, the precursor which has been brought into the vapor phase is not able to recondense in the gas feed device.

Needle valves are preferably used as valves for controlling the gas flow. Such valves have significant advantages compared to mass flow controllers (MFC). Mass flow controllers are not able to ensure constant temperatures over the entire gas path used. This may cause evaporated precursor to condense out, which entails the risk that the mass flow controller may become plugged and no longer function properly. In addition, a needle valve may be designed to be extremely heat-resistant so that it withstands temperatures up to 600° C., unlike an MFC, which does not withstand these temperatures. This may be advantageous for separation media, which must be heated to very high temperatures in the gas feed system according to the invention in order to pass into the gaseous phase.

Advantages of such a device are described in WO 2008/135516, by the same inventors as the present invention, and whose disclosure content is hereby incorporated into the present patent application.

The media listed in the following table, among others, are suitable as precursors:

TABLE 6

| | Periodic table | | |
|---|---|---|---|
| | main group | | Physical state at room |
| Material | of element | Precursor (example) | temperature |
| Ti | III | C₁₂H₂₈O₄Ti | solid |
| Ti | III | Ti[OCH(CH₃)₂]₄ | solid |
| Si | IVA | O[Si(CH₃)₃]₂ | solid |
| Ga | III | C₁₅H₂₁GaO₆ | solid |
| In | III | C₁₅H₂₁InO₆ | solid |
| Mo | VIB | C₆O₆Mo | solid |
| Cu | IB | C₁₀H₂CuF₁₂O₄ | solid |
| Cu | IB | C₁₀H₁₄CuO₄ | solid |
| Se | VIA | C₆H₅SeH | solid |
| Cd | IIB | (Cd(SC(S)N(C₂H₅)₂]₄) | solid |
| Zn | IIB | Zn(C₅H₇O₂)₂ | solid |
| Sn | IVA | C₈H₂₀Sn | liquid |

In addition, according to the invention it is provided that step

b.1) Applying an Adhesive Layer Using Plasma Coating

is carried out between step b) and step c).

The adhesive layer according to the invention contributes in various ways to improved adhesion of the cover layer to the workpiece or material, as follows:
It balances out unevennesses in the material surface
It ideally has an intermediate internal stress, i.e., an internal stress between that of the material and that of the material of the cover layer
The intermediate layer is applied with its internal stress transverse to the internal stress of the material, i.e., the substrate, and therefore has a balancing effect.

It is particularly preferably provided that the adhesive layer contains elements of subgroups VI and VII of the periodic table.

Compounds are preferably used which contain the elements Cr, Mo, W, Mn, Mg, Ti, and/or Si, and in particular mixtures thereof. In addition, the individual components may be distributed in a graduated manner over the depth of the adhesive layer. Si is particularly preferred in this regard. TMS, for example, which is highly volatile under vacuum conditions, is a suitable reaction gas.

In further preferred embodiments of the method according to the invention, it is provided that the gas feed of at least two different gases is provided in the form of oppositely directed ramps
in step a.2)
in the transition from step a.2) to step b)
in the transition from step b) to step b.1) or step c)
in the transition from step b.1) to step c).

To explain this principle, the method steps provided (in some cases optionally) according to the invention are listed in the following table.

TABLE 7

| | | | Reaction |
|---|---|---|---|
| | | | gas/method |
| Step | Status | Description | (example) |
| a.1) | Optional/ | Treating the surface of the workpiece | Sandblasting |
| | preferred | and/or material using at least one | |
| | | abrasive process | |
| a.2) | Optional/ | Activating the workpiece and/or | Ar₂ |
| | preferred | material by sputtering | |
| b) | Mandatory | Pretreating the workpiece and/or | H₂ |
| | | material by plasma reduction | |
| b.1) | Optional/ | Applying an adhesive layer by | TMS |
| | preferred | plasma coating | |
| c) | Mandatory | Applying a cover layer by plasma | C₂H₂ or |
| | | coating in a plasma coating chamber | C₄H₁₄OSi₂ |

In conjunction with the present invention, the term “in the form of oppositely directed ramps” means that, during the sputtering, plasma reduction, or application of the adhesive layer or the plasma coating, the minute volume of at least one reaction gas is reduced in a stepped or continuous manner, while the minute volume of another gas is increased in a stepped or continuous manner (see FIG. 3).

These ramps have different functions in the various steps.

For sputtering and plasma reduction, the ramps have the effect that a reaction gas is successively displaced by another reaction gas, which may be meaningful for subsequent process steps in which, for example, the first reaction gas used has an interfering effect.

For application of the adhesive layer or for plasma coating, the ramps have the effect that the deposition phases of two materials merge together. In this manner, transition regions having gradually changing portions of the various coating materials are created. This results in tighter intermeshing of the two layers, and thus, for example, better adhesion of the cover layer to the adhesive layer.

The key aspect of said ramps is that a gradual transition of at least one reaction gas to at least one other reaction gas occurs in a time-coordinated manner. [The transition from] the coating gas for the intermediate layer to the coating gas for the cover layer must be adjusted in a flowing manner using a specified time gradient. The same pertains, as applicable, to the change in the bias number and to other coating parameters.

It must be ensured that, before each transition of the reaction gases, the chamber is ramped up or ramped down to the desired bias value in order to reduce the formation of internal stress. The abrupt adjustment of the bias value must be performed at least 5 seconds, but no more than 15 seconds, before the start of adjustment of the gradient.

The transition from step b.1) to step c) may be designed, for example, so that first a silicon-containing adhesive layer is applied by plasma coating. For this purpose, for example, tetramethyldisiloxane (TMS, C₄H₁₄OSi₂), which is liquid at room temperature but highly volatile under hypobaric conditions, is used. After a certain period of time, the gas minute volume for TMS is successively decreased and the gas minute volume for the carbon-containing gas acetylene (ethene) is successively increased.

The ramp could be configured as follows: After an optional sputtering step, 5 s before starting application of the intermediate layer the bias voltage V_{bias} is raised to the level necessary for the coating. The vaporized, silane-containing TMS gas is then introduced with an extremely short ramp (10 s). After the deposition time for the adhesive layer elapses, the acetylene valve is gradually opened to the desired inlet rate over a period of 500 s. The valve for TMS is gradually closed simultaneously over the same time period. The cover layer is then applied over the desired time period. Table 8 presents this method with example values:

TABLE 8

| | | TMS | C₂H₂ | Pressure/ |
|---|---|---|---|---|
| Step | V_{bias} | (sccm) | (sccm) | temperature |
| b.1 | 200-500 | 100-500 | 0 | 0.1-2 P |
| (Adhesive layer) | | | | 50-150° C. |
| Ramp | 350 | 300 | 0 | |
| c | 250-600 | 20-150 | 100-500 | 0.01-0.9 P |
| (Cover layer) | | | | 50-150° C. |

It may particularly preferably be provided that for a transition period, the gas flow rates for the gas which generates the adhesive layer (TMS, for example) and the gas which generates the cover layer (C₂H₂, for example) are periodically modulated with respect to one another. This may be achieved in particular using an appropriately programmed mass flow controller or servo-controlled needle valves. Particularly intimate adhesion is achieved in this manner (see FIG. 2).

In principle, the application of the cover layer (step c) may have any desired duration. The thickness of the cover layer grows in proportion to the duration of the coating. It may also be provided that ramps are operated with regard to the materials used for the adhesive layer (step b.1). Thus, during the application it may be provided that one material is successively replaced by another.

Furthermore, the following method parameters are preferably maintained during application of the cover layer in the plasma coating chamber (step c):

TABLE 9

| Parameter | Value |
|---|---|
| Temperature: | 50-50° C., preferably 80° C. |
| Chamber volume: | 200-10,000 L, preferably 900 L |
| Chamber pressure: | 0.0-3.0 Pa, |
| | preferably 0.0-2.0 Pa |
| Bias voltage: | 200 volts-600 volts |
| Duration: | 1-100 min |
| Gas flow: | 50 sccm-700 sccm |

The gas concentration in the chamber results in each case from the gas flow, the volume of the chamber, and the pressure in the chamber. For a chamber having a volume of 900 L and a pressure therein of 0.0-2.0 Pa, for acetylene (C₂H₂) at a gas flow of 100 sccm (0.1175 g per minute), for example, this results in a concentration of 0.011% of the chamber volume. Examples of further preferred gas flow settings are 200 sccm (0.2350 g per minute C₂H₂=0.022%), 300 sccm (0.3525 g per minute C₂H₂ (0.033%), 400 sccm (0.4700 g per minute C₂H₂=0.044%), and 500 sccm (0.5875 g per minute C₂H₂=0.055%).

A DLC layer produced in this manner, using acetylene as reaction gas, has a hardness of 6000-8000 HV and a thickness of 0.90 μm to 5.0 μm.

To reduce the above-mentioned disadvantageous results of the sputtering using Ar₂ during this substep, the alternating electromagnetic field may be decreased during this period. As an alternative, an attempt may be made to keep the duration of this washing step as brief as possible.

The Ar₂ feed is then abruptly stopped, and the plasma reduction step takes place in which H₂ in modulated form is fed into the chamber in order to reduce/metallize any magnesium oxide still present. TMS is then introduced into the chamber. In this phase a silicon adhesive layer is applied to the surface activated by sputtering. At time T=1600 s the minute volume of TMS is successively reduced via a further ramp, and C₂H₂ is fed into the chamberinstead, resulting in deposition of DLC. Thus, in the transition period silicon and carbon are simultaneously deposited, the silicon portion being successively decreased and the carbon portion being successively increased. A transition region between the adhesive layer and the high-strength cover layer is thus produced which significantly improves the adhesion of the latter to that of the former. The cover layer is then applied over the desired period.

It is also particularly preferably provided according to the invention that during the transition between step b.1) and step c) the gas feed of the particular reaction gases is oppositely modulated, at least temporarily.

A broad transition region is thus produced between the adhesive layer and cover layer, thus improving the adhesion and reducing the occurrence of stress. It may be provided that over time, the amplitude of the periodic gas feed of the reaction gas for the adhesive layer is decreased while the amplitude of the periodic gas feed of the reaction gas for the cover layer is increased. See FIG. 3 in particular with regard to these embodiments.

Furthermore, it has proven to be advantageous to operate “continuous gradients” during the overall coating process of the cover layer in step c) in order to obtain low-stress cover layers. In practice, this means that during the overall coating process of the cover layer, the minute volume of the gas feed never remains constant, but instead the bias voltage is kept constant by periodic modulation. For example, a DLC cover layer having a thickness of up to 10 g may thus be applied in a low-stress manner. See FIG. 1 in particular with regard to these embodiments.

According to the invention, it is further provided that the method is carried out in a plasma coating chamber which has a flat high-frequency electrode for generating an alternating electromagnetic field, and a frequency generator situated outside the chamber, characterized in that the high-frequency electrode has at least two feed lines via which it is supplied with alternating voltage generated by the frequency generator.

Improved homogeneity of the alternating electromagnetic field is obtained by means of the at least two feed lines, as described in WO 2008/006856 by the same inventors as the present invention, and whose disclosure content is hereby incorporated into the present patent application.

The use of a plasma coating chamber is also provided according to the invention, having a flat high-frequency electrode for generating an alternating electromagnetic field, a frequency generator situated outside the chamber, and at least two feed lines via which the high-frequency electrode is supplied with alternating voltage generated by the frequency generator. This method is used according to the invention for applying a coating to workpieces and/or materials according to the above description.

In addition, according to the invention a workpiece and/or material containing at least one readily oxidizable nonferrous metal is provided which has a coating that is applied using a plasma coating process.

In one preferred embodiment, the coating of said workpiece or said material has at least one component selected from the group containing:
carbon, in particular diamond-like carbon (DLC)
silicon
titanium
tungsten
tungsten carbide
vanadium and/or
copper.

In addition, said workpiece and/or said material is preferably producible using a method according to the above description.

### EXAMPLES AND DRAWINGS

FIG. 1 shows by way of example the above-described periodic modulation of the reaction gas in step b) of the method according to the invention, i.e., for the plasma reduction. As previously mentioned, hydrogen gas is preferably used as reaction gas. As the result of the periodic modulation, it may be achieved that in certain phases a large quantity of reaction gas flows into the chamber, while in other phases only a small quantity of reaction gas flows into the chamber. Due to the periodic modulation of the reaction gas feed, the fissured surface of the workpiece and/or material is taken into account, since basically this is the only way to adequately reduce metal oxide residues present in deep channels and microcavities in the surface of the workpiece and/or material, as well as metal oxide residues adhering to flat passages on the surface.

The modulation may be performed, for example, in a sinusoidal manner (FIG. 1A) or a sawtoothed manner (FIG. 1B). Further options not illustrated are a triangular or square modulation. In the latter, switching is carried out back and forth between two different fixed gas flow rates.

FIG. 2 shows preferred options of the embodiment of the transition between step b.1) (applying an adhesive layer by plasma coating) and step c) (applying a cover layer by plasma coating). It is provided that for a transition period, the gas flow rates for the gas which generates the adhesive layer (TMS, for example) and the gas which generates the cover layer (C₂H₂, for example) are periodically modulated with respect to one another. This may be achieved in particular using an appropriately programmed mass flow controller or servo-controlled needle valves. Particularly intimate adhesion is achieved in this manner. As illustrated in FIG. 2A, the modulation may be carried out in a sinusoidal manner. Of course, sawtoothed, triangular, or square modulation is also conceivable.

The modulation is particularly preferably subjected to opposite modification, as illustrated in FIG. 2B. Thus, for example, the amplitude and the median of the gas flow rate for the gas generating the adhesive layer may be successively ramped down, while the amplitude and the median of the gas flow rate for the gas generating the cover layer is successively ramped up. This may be carried out for sinusoidal modulation, as illustrated, as well as for sawtoothed, triangular, or square modulation.

FIG. 3 shows the general design of the use of oppositely directed ramps. These ramps have different functions in the various steps.

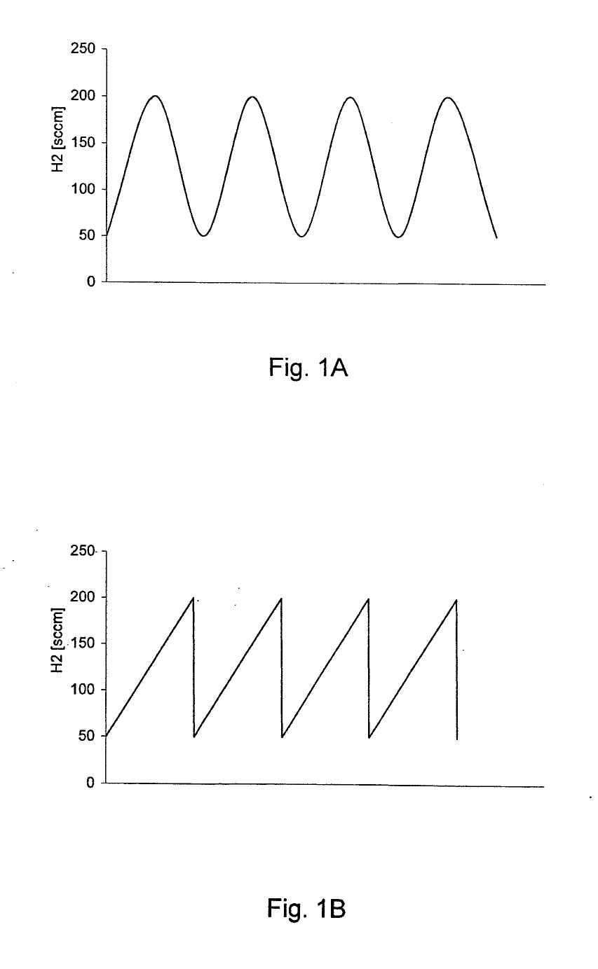

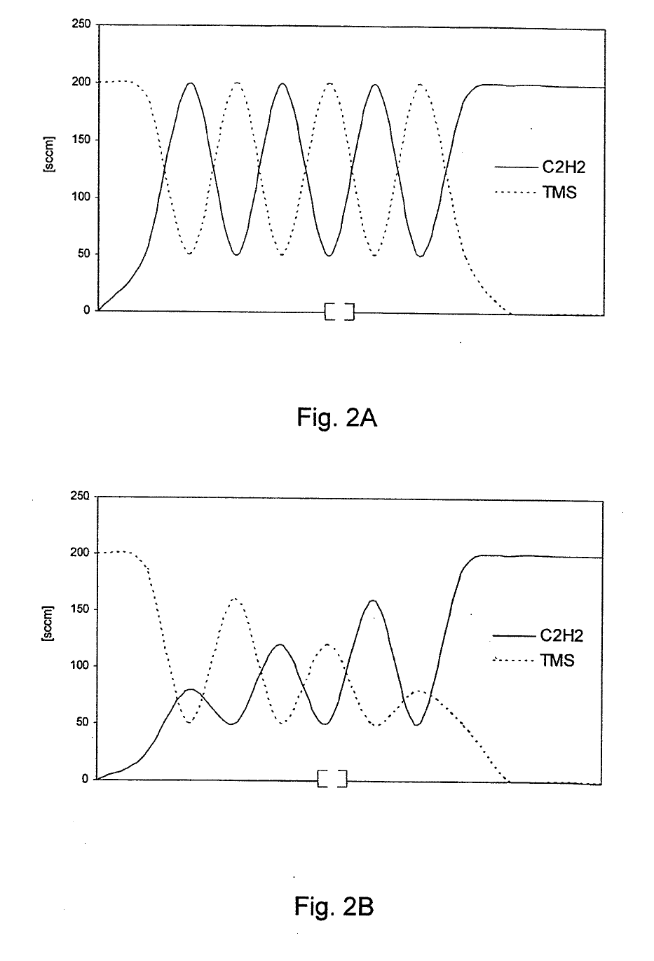

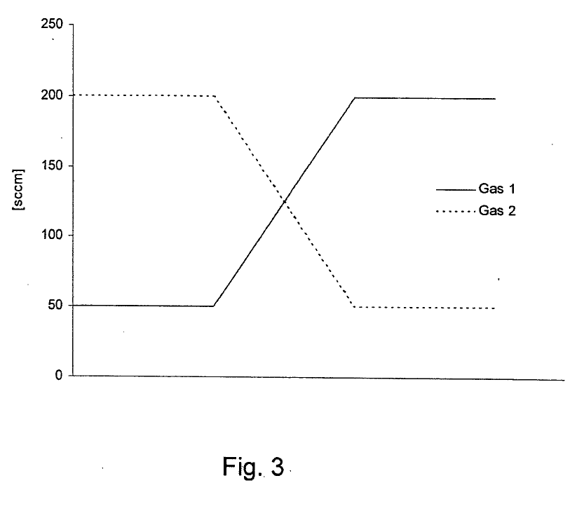

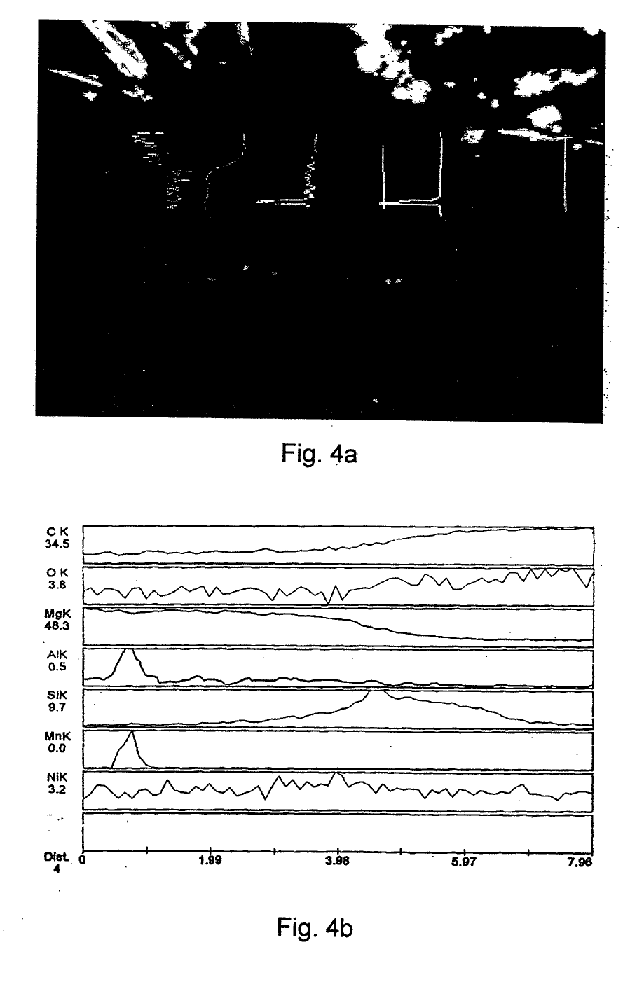

For sputtering and plasma reduction, the ramps have the effect that a reaction gas is successively displaced by another reaction gas, which may be meaningful for subsequent process steps in which, for example, the first reaction gas used has an interfering effect.

For application of the adhesive layer or for plasma coating, the ramps have the effect that the deposition phases of two materials merge together. In this manner, transition regions having gradually changing portions of the various coating materials are created. This results in tighter intermeshing of the two layers, and thus, for example, better adhesion of the cover layer to the adhesive layer.

FIG. 4a shows a scanning electron microscope image (2000× magnification) of a section of a workpiece made of a magnesium material which has been coated with DLC according to the invention. The workpiece is seen in the lower region of FIG. 4a, while the embedding medium (recognizable by the light air bubbles) is illustrated in the upper region.

Superimposed on this illustration are the concentration curves, determined by X-ray diffractometry (XRD), for carbon (C), oxygen (O), magnesium (Mg), aluminum (Al), silicon (Si), manganese (Mn), and nickel (Ni) in the transition region between the workpiece, coating, and embedding medium. Measurement and superimposition were conducted using Genesis software from Edax.

In FIG. 4b these concentration curves are illustrated separately, with the concentrations in each case plotted over a distance of 8 μm (expressed as percent by weight of the total weight of the test sample). Due to autoscaling, such elements, for which no significant changes in concentration are detectable, have strong distortion (for example, the curves for oxygen and nickel), which in the present case is bit noise. As expected, a high magnesium concentration in the region of the workpiece and a high carbon concentration in the region of the DLC coating are clearly discernible. In the transition region, the concentration of the two elements is oppositely directed due to the mentioned ramp at the beginning of step c). It is also clearly discernible that the concentration of Si briefly increases in an abrupt manner almost exactly in the transition region. This involves the silicon-containing adhesive layer (optional according to the invention), which is applied in step b.1) by plasma coating, using TMS as reaction gas. The brief, abrupt increases of aluminum and manganese present in the region of the workpiece are due to an impurity in the workpiece. It is also important that no significant higher concentration of oxygen is detectable in the transition region between the workpiece and the coating. This indicates that the metallization carried out according to the invention in step b) by plasma reduction has very efficiently expelled all of the oxygen from the material, so that the material may then be successfully provided with a durable DLC coating.

1-17. (canceled)

18. A method for applying a coating to workpieces or materials containing at least one readily oxidizable nonferrous metal or an alloy containing at least one readily oxidizable nonferrous metal, the method comprising the following steps:
b) Pretreating the workpiece or material by plasma reduction
c) Applying a cover layer to the workpiece or material by plasma coating in a plasma coating chamber,
wherein the plasma reduction of step b) comprises a reaction gas, wherein the feed of the reaction gas is periodically modulated in step b).

19. The method of claim 1, wherein the readily oxidizable nonferrous metal or alloy thereof is magnesium or a magnesium alloy.

20. The method of claim 1 wherein the reaction gas of step b) contains at least hydrogen.

21. The method of claim 1, further comprising at least one step prior to or concurrent with step b), wherein the at least one step comprises step. a.2) activating the workpiece or and/or the material by sputtering.

22. The method of claim 1, further comprising at least one step prior to step b) wherein the at least one step comprises step a.1) treating the surface of the workpiece or material using at least one abrasive process.

23. The method of claim 1, wherein the readily oxidizable nonferrous metal is tin, zinc, titanium, aluminum, beryllium, or magnesium.

24. The method of claim 1, wherein the cover layer is a carbon-containing layer, a silicon-containing layer, a titanium-containing layer, a tungsten-containing layer, a tungsten carbide-containing layer, a vanadium-containing layer, or a copper-containing layer.

25. The method of claim 1, wherein a solid or liquid precursor for a reaction gas in a gas feed system provided upstream from the plasma coating chamber is heated, brought into the vapor phase under vacuum, and subsequently fed into the plasma coating chamber via a gas feed device.

26. The method of claim 1, further comprising step b.1) applying an adhesive layer using plasma coating after step b) and prior to step c).

27. The method of claim 26, wherein the adhesive layer comprises elements of subgroups VI and VII of the periodic table.

28. The method of claim 1, wherein the gas feed of at least two different gases is provided in the form of oppositely directed ramps in step a.2), in a transition from step a.2) to step b), in a transition from step b) to step b.1), in a transition from step b) to step c), or in transition from step b.1) to step c).

29. The method of claim 26, wherein during a transition between step b.1) and step c) the gas feed of the particular reaction gases is oppositely modulated, at least temporarily.

30. The method of claim 1, wherein the method is carried out in a plasma coating chamber which has a flat high-frequency electrode for generating an alternating electromagnetic field, and a frequency generator situated outside the chamber, characterized in that the high-frequency electrode has at least two feed lines via which it is supplied with alternating voltage generated by the frequency generator.

31. Use of a plasma coating chamber, having a flat high-frequency electrode for generating an alternating electromagnetic field, a frequency generator situated outside the chamber, and at least two feed lines via which the high-frequency electrode is supplied with alternating voltage generated by the frequency generator, for applying a coating to workpieces and/or materials according to one of the preceding method claims.

32. A workpiece or material containing at least one readily oxidizable nonferrous metal, wherein the workpiece or material comprises a coating that was applied using a plasma coating process.

33. The workpiece or material of claim 32, wherein the coating material comprises carbon, diamond-like carbon (DLC), silicon, titanium, tungsten, tungsten carbide, vanadium, or copper.

34. The workpiece or material of claim 32, wherein the workpiece or material is produced by the method of claim 1.

35. The workpiece or material of claim 33, wherein the workpiece or material is produced by the method of claim 1.
